(19) United States
(12) Patent Application Publication
(10) Pub. No.: US 2014/0010951 A1
(43) Pub. Date: Jan. 9, 2014

(54) POROUS METAL IMPLANTS MADE FROM CUSTOM MANUFACTURED SUBSTRATES

(71) Applicant: Zimmer, Inc., Warsaw, IN (US)

(72) Inventors: Joseph R. Vargas, Garnerville, NY (US); Steven Seelman, Montclair, NJ (US); Emmanuel L. Uzuyem, Union, NJ (US); Joseph P. Zitelli, River Edge, NJ (US)

(21) Appl. No.: 13/926,658

(22) Filed: Jun. 25, 2013

Related U.S. Application Data
(60) Provisional application No. 61/664,241, filed on Jun. 26, 2012.

(51) Int. Cl. C23C 16/06

(52) U.S. Cl. CPC C23C 16/06
USPC 427/2.26

(57) ABSTRACT

A porous metal implant and method of manufacturing the same are disclosed. The method involves rapidly manufacturing a porous substrate layer-by-layer. The method can include the steps of depositing a first layer of a material and depositing a second layer of the material on top of the first layer. In this manner, a porous substrate having a plurality of ligaments or struts, which define a plurality of pores, can be built. The method can also include coating the porous substrate with a biocompatible metal to strengthen and stabilize the porous substrate for implantation.

### CLAIM OF PRIORITY

This patent matter claims the benefit of priority under 35 U.S.C. §119(e) of U.S. Provisional Patent Application Ser. No. 61/664,241, entitled “POROUS METAL IMPLANTS MADE FROM CUSTOM MANUFACTURED SUBSTRATES,” filed on Jun. 26, 2012, which is herein incorporated by reference in its entirety.

### TECHNICAL FIELD

The present disclosure relates to porous metal implants.

### BACKGROUND

Prosthetic orthopaedic implants are commonly used to replace at least a portion of a patient's bone following traumatic injury or deterioration due to aging, illness, or disease, for example.

When implanted into a joint, the prosthetic orthopaedic implant may be configured to articulate with an adjacent orthopaedic component. For example, a prosthetic orthopaedic implant that is implanted into a patient's hip joint may be socket-shaped to receive and articulate with an adjacent femoral component.

The prosthetic orthopaedic implant may be at least partially porous to promote ingrowth of the patient's surrounding bone and/or soft tissue. Such ingrowth may enhance the fixation between the implant and the patient's surrounding bone and/or soft tissue.

An example of a porous implant material is produced using Trabecular Metal™ technology generally available from Zimmer, Inc., of Warsaw, Ind. Trabecular Metal™ is a trademark of Zimmer, Inc. Such a material may be formed by converting a polymer foam into a reticulated vitreous carbon (RVC) foam, and then coating and infiltrating the RVC foam substrate with a biocompatible metal in the manner disclosed in U.S. Pat. No. 5,282,861 to Kaplan, the entire disclosure of which is expressly incorporated herein by reference. The polymer foam may be provided in a bulk shape (e.g., a block or a sheet), so that the RVC foam or the metal-coated foam may require shaping of the bulk shape (e.g., machining) to arrive at a shape that is suitable or desirable for implantation.

### OVERVIEW

The present disclosure provides a porous metal implant and method of manufacturing the same. The method can involve rapidly manufacturing a porous substrate layer-by-layer. The method can also involve coating the porous substrate with a biocompatible metal to strengthen and stabilize the porous substrate for implantation.

According to an example embodiment of the present disclosure, a method is provided for manufacturing a porous implant. The method can include the steps of depositing a first layer of a material, depositing a second layer of the material on top of the first layer to build a porous substrate having a plurality of ligaments or struts that define pores, the first and second layers of material cooperating to form at least one of the plurality of ligaments or struts of the porous substrate, and coating the plurality of ligaments or struts of the porous substrate with a biocompatible metal coating.

To better illustrate the porous metal implants disclosed herein, a non-limiting list of embodiments is provided here:

In Embodiment 1, a method of manufacturing a porous implant comprising the steps of depositing a first layer of material, depositing a second layer of material on top of the first layer of material to build a porous substrate with a plurality of ligaments or struts that define pores, the first and second layers of material cooperating to form at least one of the plurality of ligaments or struts of the porous substrate; and coating the plurality of ligaments or struts of the porous substrate with a biocompatible metal coating.

In Embodiment 2, the method of claim 1 can optionally be modified such that the first and second layers of material are deposited with the material in a powdered state, the method further comprising the step of converting the material from the powdered state to a solid state.

In Embodiment 3, the method of any one or any combination of Embodiments 1 or 2 can optionally be modified to further comprise the step of applying an energy source to the second layer of material to couple the second layer of material to the first layer of material.

In Embodiment 4, the method of any one or any combination of Embodiments 1 to 3 can optionally be modified such that the coating step comprises performing a chemical vapor deposition process.

In Embodiment 5, the method of any one or any combination of Embodiments 1 to 4 can optionally be modified to further comprise the step of allowing the first and second layers of material to harden before the coating step.

In Embodiment 6, the method of any one or any combination of Embodiments 1 to 5 can optionally be modified such that the first and second layers of material in the porous substrate comprise titanium or a titanium alloy and the biocompatible metal coating comprises tantalum or a tantalum alloy.

In Embodiment 7, the method of any one or any combination of Embodiments 1 to 6 can optionally be modified such that the first and second layers of material comprise a metal different from the biocompatible metal coating.

In Embodiment 8, the method of any one or any combination of Embodiments 1 to 7 can optionally be modified such that the depositing steps build the porous substrate in a net shape that is suitable for implantation.

In Embodiment 9, the method of any one or any combination of Embodiments 1 to 8 can optionally be modified such that the porous substrate has a porosity of at least about 55%,

In Embodiment 10, the method of any one or any combination of Embodiments 1 to 9 can optionally be modified such that the porous substrate has an average pore size between about 100 μm and about 1,000 μm.

In Embodiment 11, the method of any one or any combination of Embodiments 1-10 can optionally be configured such that all elements or options recited are available to use or select from.

These and other examples and features of the present methods are set forth in part in the following Detailed Description. This Overview is intended to provide non-limiting examples of the present subject matter—it is not intended to provide an exclusive or exhaustive explanation. The Detailed Description below is included to provide further information about the present subject matter.

### BRIEF DESCRIPTION OF THE DRAWINGS

The above-mentioned and other features and advantages of this disclosure, and the manner of attaining them, will become more apparent and the invention itself will be better understood by reference to the following description of embodiments of the invention taken in conjunction with the accompanying drawings, wherein:

FIG. 1 is a flow chart of an example method for manufacturing a porous metal implant from a custom porous substrate;

FIG. 2 is a schematic view of a porous substrate of the present disclosure;

FIG. 3 is a schematic diagram showing a first layer of metal powder applied across a build chamber;

FIG. 4 is another schematic diagram showing a laser selectively converting the first layer of metal powder from FIG. 3 to solid metal;

FIG. 5 is another schematic diagram showing a second layer of metal powder applied across the first layer;

FIG. 6 is another schematic diagram showing the laser selectively converting the second layer of metal powder from FIG. 5 to solid metal;

FIG. 7 is another schematic diagram showing a third layer of metal powder applied across the second layer;

FIG. 8 is another schematic diagram showing the laser selectively converting the third layer of metal powder from FIG. 7 to solid metal;

FIG. 9 is another schematic diagram showing a final layer of metal powder converted to solid metal to arrive at the porous substrate of FIG. 2;

FIG. 10 is a schematic view of a porous implant of the present disclosure made by coating the porous substrate of FIG. 2, a portion of the porous implant being depicted in cross-section to show the coating on the porous substrate; and

FIG. 11 is a schematic view of a chemical vapor deposition (CVD) apparatus for coating the porous substrate of FIG. 2.

Corresponding reference characters indicate corresponding parts throughout the several views. The examples set out herein illustrate exemplary embodiments of the invention and such exemplifications are not to be construed as limiting the scope of the invention in any manner.

### DETAILED DESCRIPTION

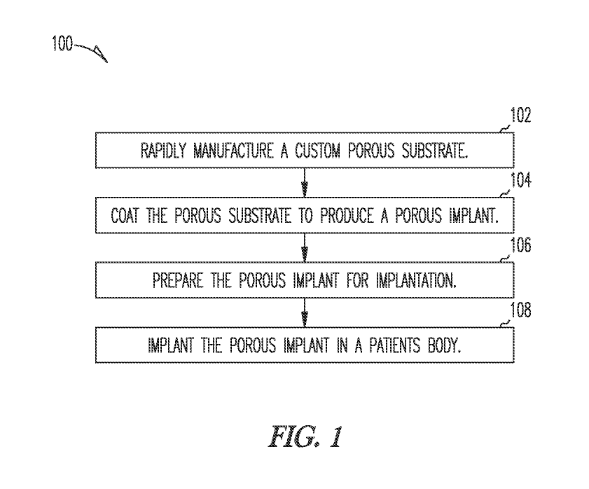

FIG. 1 provides an example method 100 for manufacturing a porous metal implant.

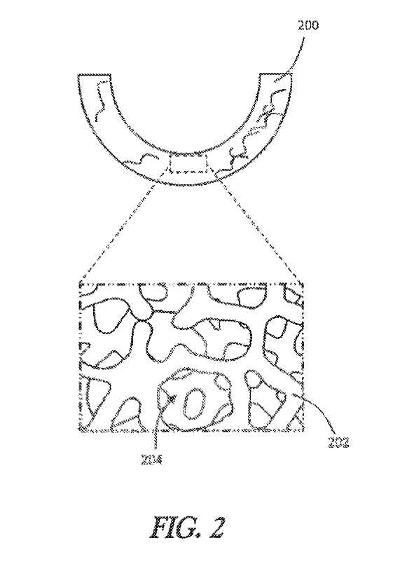

Beginning at step 102 of method 100 (FIG. 1), a custom porous substrate is manufactured. An example porous substrate 200 is shown in FIG. 2 with a large plurality of struts or ligaments 202 that define open spaces or pores 204 therebetween. Pores 204 between struts or ligaments 202 may form a matrix of continuous channels having no dead ends, such that growth of cancellous bone and/or soft tissue through porous substrate 200 is uninhibited. Thus, porous substrate 200 may provide a matrix into which cancellous bone and/or soft tissue may grow to provide fixation of porous substrate 200 to the patient's bone.

During the manufacturing step 102 (FIG. 1), porous substrate 200 may be fabricated to virtually any desired porosity (pore density), pore orientation, and/or location within the porous substrate, pore shape, and pore size in order to selectively tailor porous substrate 200 for a particular application, such as for a specific implant device, implantation procedure or surgical or implant site. For example, porous substrate 200 may be fabricated to a porosity as low as about 55%, 65%, or 75%, and as high as about 80%, 85%, 90%, or more, or within any range delimited by any pair of the forgoing values. Also, porous substrate 200 may be fabricated to an average pore size as low as about 100 μm, 300 μm, or 500 μm, and as high as about 700 μm, 900 μm, or 1,000 μm, or within any range delimited by any pair of the forgoing values.

In an embodiment, the porous metal implant can be specifically configured and customized (e.g., through pore density, pore size, pore shape and/or pore location, orientation and/or direction within the substrate) such that the modulus or strength of the porous metal implant is optimized for a specific implant type, or implantation procedure, or surgical or implantation site. In yet another embodiment, the porous implant can include a porous substrate that can be specifically configured and customized (e.g., through pore density, pore size, pore shape and/or pore location, orientation and/or direction within the substrate) to positively or negatively influence the stress exerted on, or the remodeling of, a bone adjacent to the implantation site of the porous metal implant. For example, the porous metal implant can be custom manufactured such that it has a modulus that is substantially the same as, or slightly less than the modulus of the adjacent bone, thereby having a positive influence on the stress exerted on, or remodeling of, the bone. Alternatively, the porous metal implant can be custom manufactured such that it has a modulus that is greater than the modulus of the adjacent bone, thereby having a negative influence on the stress exerted on, and remodeling of, the adjacent bone.

For example, a distal end of a primary hip stem implant designed for proximal stem fixation can be custom manufactured such that the pores if the implant are configured (e.g., through pore density, pore size, pore shape and/or pore location, orientation and/or direction within the substrate) to resist bone bridging adjacent the distal tip when the hip stem implant is implanted. In an alternate example, such as a revision hip stem intended for implantation adjacent proximal bone of poor quality, the revision hip stein implant can be custom manufactured such that the pores can be designed or configured (e.g., through pore density, pore size, pore shape and/or pore location, orientation and/or direction within the substrate) to encourage fixation of the distal end of the hip stem implant to the bone.

In certain embodiments, the implant is manufactured so that the implant includes a gradation in the pore density or pore size, or a variation in pore shape or orientation, from the bone/porous implant interface to the interior of the porous implant or from the proximal to distal end of the porous metal implant, to customize the modulus or strength of the porous metal implant for a specific implant type, a specific implantation procedure, a specific surgical or implantation site, or for a specific patient anatomy based on medical imaging, pre-operation evaluations of the patient (e.g., joint kinematics, anatomical defects or deficiencies, and lifestyle or other factors that may affect joint kinematics, bone density or bone health) and/or medical history.

In still other embodiments, the implant is manufactured in such a way that there is a gradation in pore orientation to customize the modulus or strength of the porous metal implant. In an example, a hemispherical acetabular shell can be custom manufactured to include a tapered conical pore design having a virtual initiation point of all of the tapers originating at the center of rotation of the femoral head that would be articulating within porous metal acetabular shell implant.

The porous structure and the overall implant is designed, manufactured in layers, and treated with a final coating layer according the the methods described herein, based on input from appropriate measurements of the surgical site, bone quality adjacent the surgical site, joint kinematics, patient health and medical history, and projected reconstruction.

Additionally, during the manufacturing step 102 (FIG. 1), porous substrate 200 may be fabricated in a desired shape and size that is suitable for implantation in a patient's body (i.e., a net shape). The illustrative porous substrate 200 of FIG. 2, for example, is provided in a hollow hemispherical shape and in a size that is suitable for implantation in a patient's hip joint as a prosthetic acetabular component. It is also within the scope of the present disclosure that the porous substrate may be shaped and sized for use as a prosthetic femoral component, a prosthetic tibial component, a prosthetic humeral component, a prosthetic spinal component, a prosthetic dental component, or another prosthetic orthopaedic component, for example. It is also within the scope of the present disclosure that porous substrate 200 may be manufactured in a near net shape and then undergo subsequent shaping (e.g., machining) before implantation.

An example porous substrate 200 is constructed of metal, such as titanium, a titanium alloy (e.g., Ti-6Al-4V), cobalt, or a cobalt-chromium alloy. However, other materials may be used to construct porous substrate 200 if such materials are capable of withstanding the necessary anatomical forces when implanted.

According to an example embodiment of the present disclosure, the manufacturing step 102 (FIG. 1) is performed using a rapid manufacturing process, more specifically a rapid additive manufacturing process. Rapid additive manufacturing processes build struts or ligaments 202 of porous substrate 200 by laying down and solidifying material layer-by-layer. Suitable rapid additive manufacturing processes may include, for example, 3-D printing, selective laser sintering (SLS), direct metal laser sintering (DMLS), selective laser melting (SLM), electron beam melting (EBM), fused deposition modeling (FDM), stereolithography (SLA), and laser engineered net shaping (LENS).

Advantageously, such rapid additive manufacturing processes allow porous substrate 200 to be built in desired shapes and sizes. The overall size and shape of porous substrate 200 may be controlled, which enables construction of porous substrates 200 in net shapes or near net shapes with little or no subsequent shaping required. The ability to control the overall size and shape of porous substrate 200 also enables construction of porous substrates 200 have highly complex geometries for patient-specific applications, for example. In addition to controlling the overall size and shape of porous substrate 200, the size, shape, and placement of each individual ligament 202 of porous substrate 200 may be controlled, which enables control over the number or density, the shape and size of pores 204 located between ligaments or struts 202, and the location, orientation and/or direction of the pores 204 within the porous metal implant.

Also advantageously, such rapid additive manufacturing processes allow porous substrate 200 to be built in a rapid, automated manner for efficiency and reproducibility. Furthermore, such processes allow porous substrate 200 to include both porous areas with pores 204 and solid areas without pores, where the solid areas may serve as supports, bearing surfaces for articulation, or attachment surfaces for mechanical fasteners, for example.

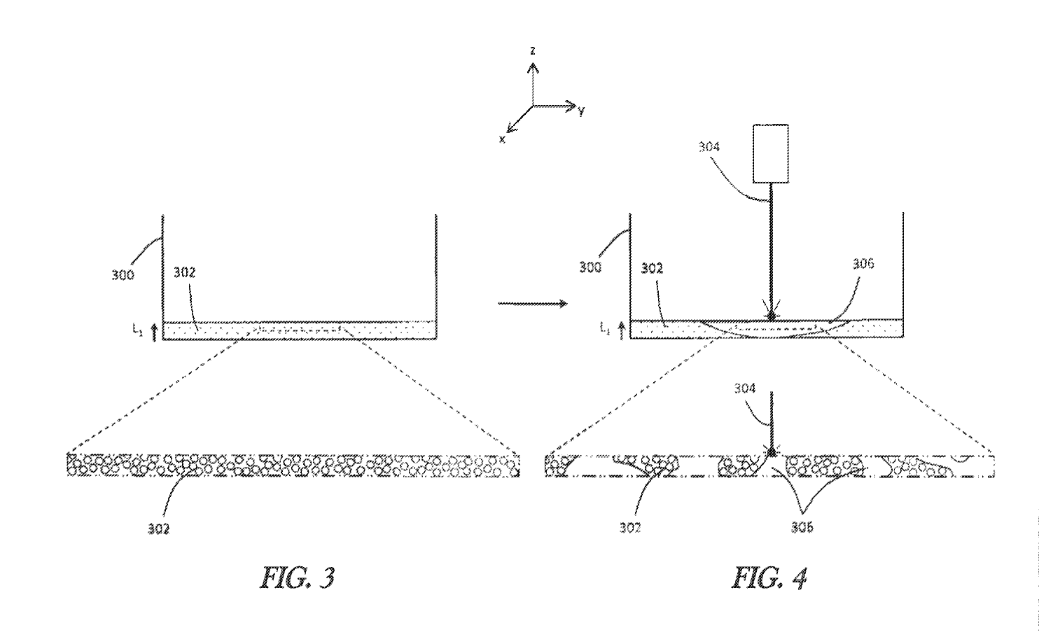

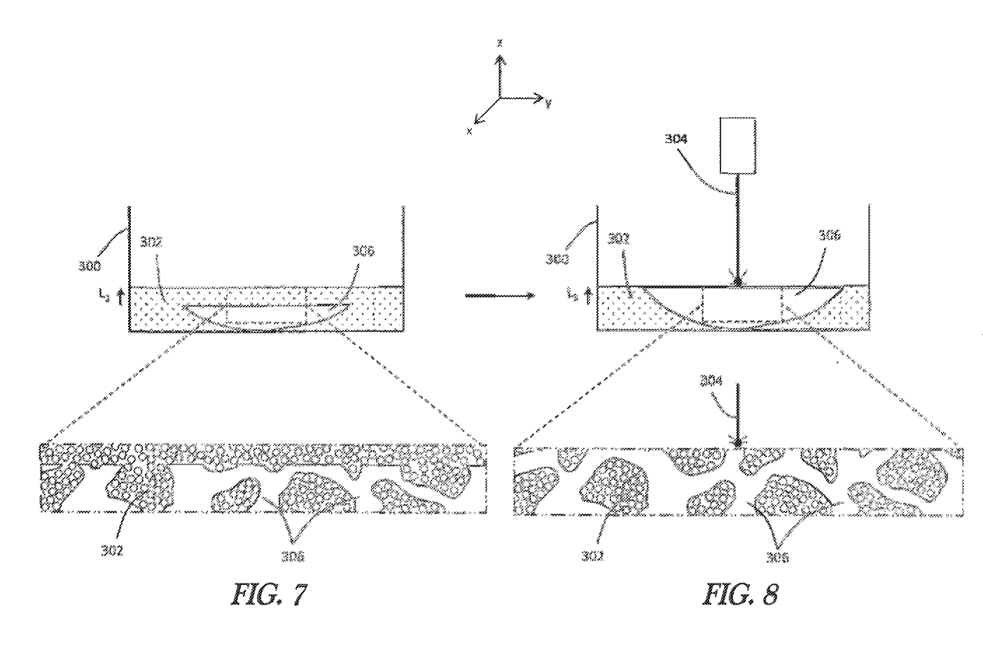

An example rapid additive manufacturing process will now be described with reference to FIGS. 3-9. The illustrative process involves laying down successive layers of metal powder, and then applying energy to certain areas of each metal powder layer to selectively sinter and/or melt the metal powder. The sintered or melted metal powder fuses together with surrounding material in the same layer and in adjacent layers to form ligaments or struts 202 of porous substrate 200 (FIG. 2).

A suitable build chamber 300 is shown in FIG. 3. Build chamber 300 may be evacuated and flushed with an inert gas (e.g., argon) to avoid oxidation. Build chamber 300 may be equipped with a heater (not shown), if necessary. Also, build chamber 300 may be equipped with a leveling mechanism, such as a roller (not shown), which is discussed further below.

The illustrative rapid additive manufacturing process begins by depositing a first layer L₁ of metal powder 302 into build chamber 300, as shown in FIG. 3. As mentioned above, metal powder 302 may include, for example, titanium powder, a titanium alloy (e.g., Ti-6Al-4V) powder, cobalt powder, or a cobalt-chromium alloy powder. In an example embodiment, the first layer L₁ of metal powder 302 (and each subsequent layer of metal powder 302) is about 20 micrometers to about 30 micrometers thick. After depositing the first layer L₁ of metal powder 302 (and each subsequent layer of metal powder 302) into build chamber 300, metal powder 302 may be leveled by rolling a roller (not shown) across build chamber 300, by vibrating build chamber 300, or by another suitable leveling technique.

The illustrative rapid additive manufacturing process continues by exposing select areas of the first layer L₁ of metal powder 302 to an energy source 304, as shown in FIG. 4. The energy source 304 may be focused and high-powered to cause localized sintering or melting of metal powder 302 particles, which converts select areas of metal powder 302 to solid metal 306. If metal powder 302 is a Ti-6Al-4V powder, for example, the energy applied by the source 304 may cause select areas of metal powder 302 to approach and/or reach its melting point of about 1,700° C. to achieve localized sintering or melting. The energy source 304 may be in the form of a laser (e.g., a ytterbium fiber optic laser), an electron beam, or another suitable energy source. When cooled and hardened, each newly-formed region of solid metal 306 may bond to surrounding regions of solid metal 306, as shown in FIG. 4. In this manner, solid metal 306 is selectively and rapidly formed in build chamber 300.

The energy source 304 may be automatically controlled using a suitable computer processor having, for example, computer-aided design (CAD) software and/or computer-aided manufacturing (CAM) software installed thereon. Such software can be used to rapidly create computer numerical control (CNC) code that will control each individual pass of the energy source 304 across build chamber 300. For example, after the first layer L₁ of metal powder 302 (and each subsequent layer of metal powder 302) is deposited into build chamber 300 (i.e., along the z-axis), the CNC code may automatically direct the energy source 304 side-to-side across build chamber 300 (i.e., along the y-axis) and back-and-forth across build chamber 300 (i.e., along the x-axis). To convert select areas of metal powder 302 to solid metal 306, the energy source 304 may be activated at select xy-coordinates. To leave other areas of metal powder 302 as is, without forming solid metal 306, the energy source 304 may be deactivated at other xy-coordinates or may avoid traveling to those xy-coordinates altogether. In this manner, the energy source 304 is able to form solid metal 306 in the first layer L₁ (and in each subsequent layer) in a predetermined pattern.

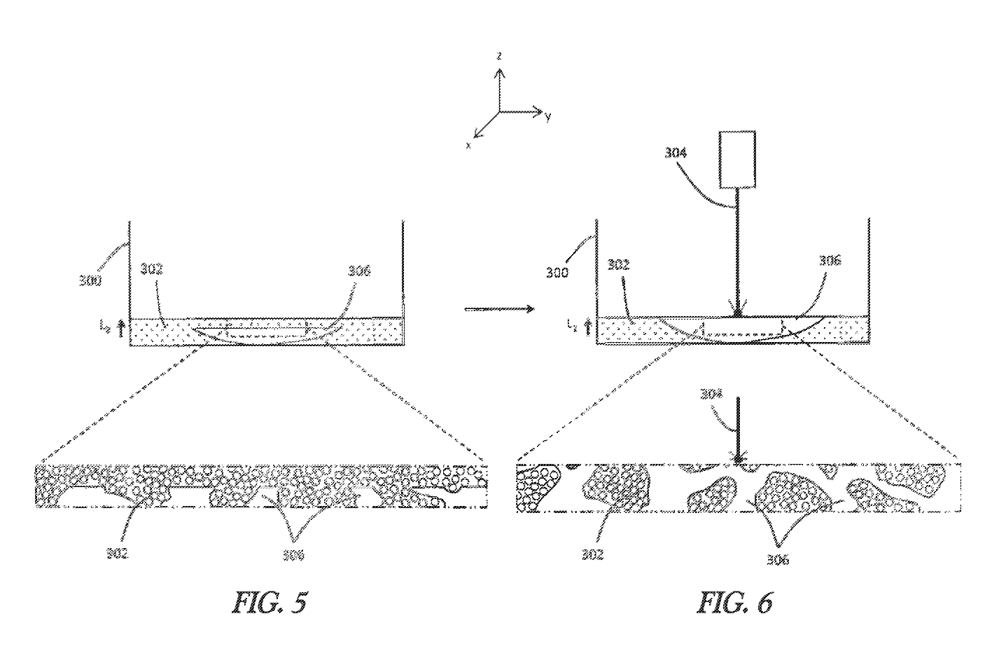

As shown in FIGS. 5-9, the above-described steps of the rapid additive manufacturing process are repeated to deposit successive layers L₂, L₃, . . . Lₙ of metal powder 302 into build chamber 300 atop the first layer L₁ and to convert additional areas of metal powder 302 to solid metal 306. In some areas, the pattern of solid metal 306 in adjacent layers L₁, L₂, L₃, . . . Lₙ may differ. For example, a region of solid metal 306 in the second layer L₂ may overlap a region of metal powder 302 in the first layer L₁. In other areas, the pattern of solid metal 306 in adjacent layers L₁, L₂, L₃, . . . Lₙ may overlap. When cooled and hardened, the overlapping areas of solid metal 306 in adjacent layers L₁, L₂, L₃, . . . Lₙ will couple together and cooperate to form ligaments or struts 202 of porous substrate 200 (FIG. 2). As discussed above, the ability to convert select areas of metal powder 302 to solid metal 306 allows the overall size and shape of porous substrate 200 to be customized, as well as the size, shape, and placement of each individual ligament 202 of porous substrate 200 and the pores 204 located therebetween.

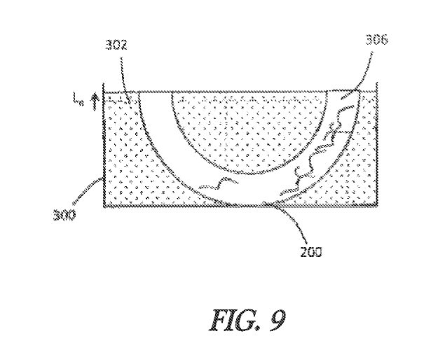

After solid metal 306 is allowed to sufficiently harden, the porous substrate 200 of FIG. 9 may be removed from build chamber 300, leaving behind metal powder 302 that was not converted to solid metal 306. Excess metal powder 302 that is captured in pores 204 between ligaments or struts 202 (FIG. 2) may be removed by shaking porous substrate 200 and/or by blowing pressurized air into porous substrate 200, for example. Constructing open pores 204 that communicate with one another facilitates the escape of metal powder 302 from porous substrate 200.

In the illustrated rapid additive manufacturing process of FIGS. 3-9, the metal powder particles are sintered and/or melted after being laid down across build chamber 300. It is also within the scope of the present disclosure to sinter and/or melt the metal powder particles before or while laying down the particles. For example, the above-mentioned LENS process involves delivering metal powder particles to a deposition head, directing a laser beam through the deposition head to melt the metal powder particles, and then laying down the molten particles in select areas. Regardless of the state or type of material being laid, the rapid additive manufacturing processes of the present disclosure allow porous substrate 200 to be built layer-by-layer.

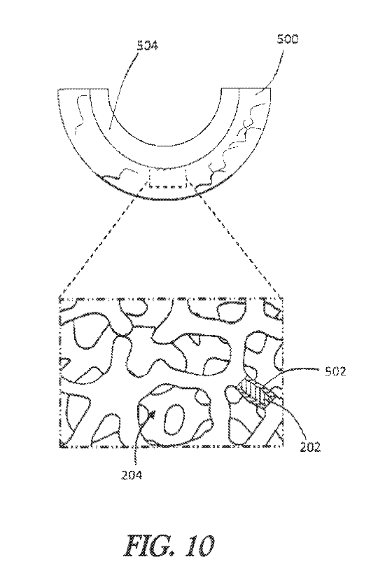

Returning to method 100 of FIG. 1, the custom, porous substrate 200 from the rapid manufacturing step 102 is coated in step 104 to produce a custom, porous implant 500, as shown in FIG. 10. More specifically, the ligaments or struts 202 of the custom, porous substrate 200 are coated in step 104, such that the underlying ligaments or struts 202 serve as a skeleton for the coating 502 that is applied during step 104.

The coating step 104 allows a first metal or other material to be used for the rapid manufacturing step 102 and a different, second metal to be used for the coating step 104. In an example embodiment, the first metal has a relatively low melting point to facilitate conversion of metal powder 302 to solid metal 306 during the rapid manufacturing step 102, and the second metal is strong and highly biocompatible to facilitate implantation after the coating step 104. For example, the first metal from the rapid manufacturing step 102 may include titanium or a titanium alloy (e.g., Ti-6Al-4V), and the second metal from the coating step 104 may include tantalum or a tantalum alloy.

According to an example embodiment of the present disclosure, the coating step 104 (FIG. 1) is performed by chemical vapor deposition (CVD). The CVD process may enable the coating 502 to both surround and infiltrate porous substrate 200, coating both exterior ligaments or struts 202 of porous substrate 200 and interior struts or ligaments 202 within porous substrate 200, as shown in FIG. 10. As indicated above, the coating 502 may strengthen porous substrate 200 and improve the biocompatibility of porous substrate 200 for implantation.

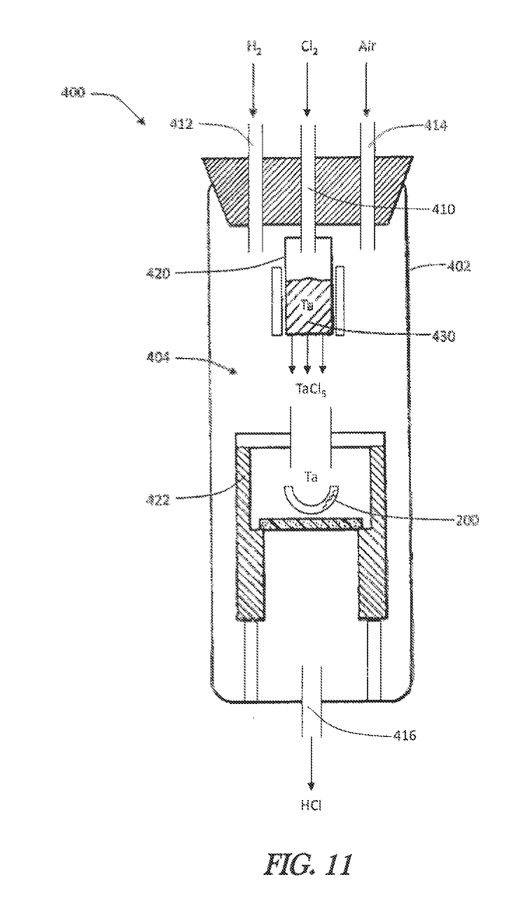

An example CVD apparatus 400 is shown in FIG. 11, but it is understood that the design of apparatus 400 may vary. Apparatus 400 includes housing 402 that defines an internal reaction chamber 404. Apparatus 400 includes a chlorine (Cl₂) gas input 410, a hydrogen (H₂) gas input 412, and an air input 414 into reaction chamber 404, each having a suitable flow control valve (not shown). Apparatus 400 also includes an exhaust gas output 416 from reaction chamber 404. Within reaction chamber 404, apparatus 400 includes a heated chlorination chamber 420 and a heated deposition chamber or furnace 422. A supply of tantalum 430 or another biocompatible metal is located within chlorination chamber 420. The rapidly manufactured porous substrate 200 is placed within deposition chamber 422.

In operation, Cl₂ gas is injected via input 410 and H₂ gas is injected via input 412 into reaction chamber 404, which may be held under vacuum at a pressure of 1.0 to 2.0 Torr. Once inside the heated chlorination chamber 420, which may be resistance-heated to a temperature of approximately 500° C., the Cl₂ gas reacts with tantalum 430 to form tantalum chloride gas, such as TaCl₅ gas. The TaCl₅ gas then mixes with the injected H₂ gas and travels into the heated deposition chamber 422, which may be induction-heated to a temperature of approximately 900° C.-1,100° C., and more specifically to a temperature of approximately 900° C.-970° C. Once inside the heated deposition chamber 422, the TaCl₅ and H₂ gases flow around and into the porous substrate 200. Then, upon contact with the heated surfaces of porous substrate 200, the TaCl₅ and H₂ gases react to deposit tantalum metal and to liberate hydrogen chloride (HCl) gas. The liberated tantalum metal is deposited as a thin, substantially uniform film or coating 502 onto exterior and interior ligaments or struts 202 of porous substrate 200 (FIG. 10). The HCl gas is then exhausted via exhaust gas output 416 from reaction chamber 404, along with excess reactant gases. Additional information regarding the CVD process is set forth in the above-incorporated U.S. Pat. No. 5,282,861 to Kaplan.

To promote even metal deposition and infiltration, the porous substrate 200 may be flipped and/or rotated in apparatus 400 during the CVD process or between individual cycles of the CVD process. Also, porous substrate 200 may be moved to different locations in apparatus 400, especially when multiple porous substrates 200 are coated simultaneously in apparatus 400. For example, when apparatus 400 contains a stack of porous substrates 200, a certain substrate may be located on top of the stack during a first CVD cycle and then may be moved to the bottom of the stack during a second CVD cycle.

In certain embodiments, the coating of the plurality of struts and ligaments 202 of the porous substrate with a biocompatible metal coating is designed to produce a specific macro-, micro- or nano-topography to modify a biological response to the porous metal implant when implanted in the body. In still other embodiments, the macro-, micro- or nano-topography of the layered metals comprising the porous structure, and the macro-, micro-, or nano-topography of the biocompatible metal coating are each adjusted to modify a biological response to the porous metal implant when implanted in the body. Such modified biological response can include a modified cellular migration, cellular adhesion to the porous metal implant and/or cell proliferation therein. In some embodiments, the response can be a positive response, wherein one or more of cell migration, cell adhesion and cell proliferation are promoted. In other embodiments, the response can be a negative response, wherein one or more of cell migration, cell adhesion and cell proliferation are inhibited or disrupted. In certain embodiments, the biological response is the response of a human cell, while in other embodiments the biological response is the response of a bacterial cell.

In certain embodiments, the coating of the porous substrate with a biocompatible metal coating is configured or designed to produce a specific nano-topography to enhance the bone or soft tissue integration to the implant when the porous metal implant is implanted in the body. In alternate embodiments, the coating of the porous substrate with a biocompatible metal coating is configured or designed to produce a specific nano-topography to disrupt or inhibit bone or soft tissue integration to the porous metal implant when implanted in the body. In still other embodiments, the coating of the porous substrate with a biocompatible metal coating is configured or designed to produce a specific nano-topography to create an antimicrobial surface on the porous metal implant when implanted in the body.

In certain embodiments, the coating step 104 is optional. For example, if the first metal that is used to produce porous substrate 200 during the rapid manufacturing step 102 is suitable for direct implantation (e.g., tantalum), the coating step 104 can be avoided. In such embodiments, porous substrate 200 can be considered a porous implant 500 that is ready for implantation after the rapid manufacturing step 102, even without the coating step 104.

Returning to method 100 of FIG. 1, the porous implant 500 from the manufacturing step 102 or the optional coating step 104 may be prepared for implantation in step 106. The preparing step 106 can include any necessary shaping, processing, sterilizing, or packaging steps. For example, a polymeric bearing component 504 may be secured onto the porous implant 500, as shown in FIG. 10, to form an articulating, joint replacement implant. Example methods for attaching a polymeric bearing component to a highly porous material are described in U.S. Patent Application Publication No. 2009/0112315 to Fang et al., the entire disclosure of which is expressly incorporated herein by reference. As another example, porous implant 500 may be coupled to a solid metal substrate (not shown), such as by sintering or diffusion bonding. Example methods for attaching a highly porous material to a solid metal substrate are described in U.S. Pat. No. 7,918,382 to Charlebois et al. and in U.S. Pat. No. 7,686,203 to Rauguth et al., the entire disclosures of which are expressly incorporated herein by reference. Another example method for coupling porous implant 500 to a solid metal substrate is resistance welding, which is described in U.S. Patent Application Publication No. 2012/0125896 to Vargas et al., the entire disclosure of which is expressly incorporated herein by reference.

Finally, in step 108 of method 100 (FIG. 1), porous implant 500 is implanted into the patient's body. The illustrative porous implant 500 of FIG. 10 is hemispherical in shape and is configured to be implanted into the patient's hip joint as a prosthetic acetabular component. It is also within the scope of the present disclosure that porous implant 500 may be a prosthetic proximal femoral component for use in the patient's hip joint, a prosthetic distal femoral component for use in the patient's knee joint, a prosthetic tibial component for use in the patient's knee joint, a prosthetic humeral component for use in the patient's shoulder joint, a prosthetic spinal component, or a prosthetic dental component, for example. Porous implant 500 may also be in the shape of a plate, plug, or rod, for example. Porous implant 500 may be secured in place using suitable fasteners (e.g., bone screws) or bone cement, for example. Over time, porous implant 500 will facilitate ingrowth of the patient's surrounding bone and/or soft tissue.

The above Detailed Description includes references to the accompanying drawings, which form a part of the Detailed Description. The drawings show, by way of illustration, specific embodiments in which various methods can be practiced. These embodiments are also referred to herein as “examples.”

While this invention has been described with reference to certain examples, the present invention can be further modified within the spirit and scope of this disclosure. This patent matter is therefore intended to cover any variations, uses, or adaptations of the invention using its general principles. Further, this patent matter is intended to cover such departures from the present disclosure as come within known or customary practice in the art to which this invention pertains and which fall within the limits of the appended claims.

The above Detailed Description is intended to be illustrative, and not restrictive. For example, the above-described examples (or one or more elements thereof) can be used in combination with each other. Other embodiments can be used, such as by one of ordinary skill in the art upon reviewing the above description. Also, various features or elements can be grouped together. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

In the event of inconsistent usages between this document and any document so incorporated by reference, the usage in this document controls.

In this document, the terms “a” or “an” are used to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated.

In the appended claims, the terms “having,” “including” and “in which” are used as the plain-English equivalents of the respective terms “comprising” and “wherein.” The terms “having”, “including” and “comprising” are open-ended, that is, an apparatus, system, kit, or method that includes elements in addition to those listed after such a term in a claim are still deemed to fall within the scope of that claim. Moreover, in the following claims, the terms “first,” “second,” and “third,” etc, are used merely as labels, and are not intended to impose numerical requirements on their objects.

The Abstract is provided to allow the reader to quickly ascertain the nature of the technical disclosure. It is submitted with the understanding that it will not be used to interpret or limit the scope or meaning of the claims.

What is claimed is:

1. A method of manufacturing a porous implant, comprising:
depositing a first layer of material;
depositing a second layer of material on top of the first layer of material to build a porous substrate with a plurality of ligaments that define pores, the first and second layers of material cooperating to form at least one of the plurality of ligaments of the porous substrate; and
coating the plurality of ligaments of the porous substrate with a biocompatible metal coating.

2. The method of claim 1, wherein the first and second layers of material are deposited with the material in a powdered state, the method further comprising converting the material from the powdered state to a solid state.

3. The method of claim 2, further comprising applying an energy source to the second layer of material to couple the second layer of material to the first layer of material.

4. The method of claim 1, wherein coating the plurality of ligaments comprises performing a chemical vapor deposition process.

5. The method of claim 1, further comprising allowing the first and second layers of material to harden before coating.

6. The method of claim 1, wherein the first and second layers of material in the porous substrate comprise titanium or a titanium alloy and the biocompatible metal coating comprises tantalum or a tantalum alloy.

7. The method of claim 1, wherein the first and second layers of material comprise a metal different from the biocompatible metal coating.

8. The method of claims 1, wherein depositing the first and second layers of material includes building the porous substrate in a net shape that is suitable for implantation.

9. The method of claim 1, wherein the porous substrate has a porosity of at least about 55%.

10. The method of claim 1, wherein the porous substrate has an average pore size between about 100 μm and about 1,000 μm.
